(19) United States
(12) Patent Application Publication
(10) Pub. No.: US 2011/0095398 A1
(43) Pub. Date: Apr. 28, 2011

(54) BIPOLAR SEMICONDUCTOR DEVICE AND METHOD OF PRODUCING SAME

(75) Inventors: Kenichi NONAKA, SAITAMA (JP); Hideki HASHIMOTO, SAITAMA (JP); Seiichi YOKOYAMA, SAITAMA (JP); Akihiko HORIUCHI, SAITAMA (JP); Yuki NEGORO, SAITAMA (JP); Norio TSUYUGUCHI, SAITAMA (JP); Takeshi ASADA, SAITAMA (JP); Masaaki SHIMIZU, SAITAMA (JP)

(73) Assignees: HONDA MOTOR CO., LTD., TOKYO (JP); SHINDENGEN ELECTRIC MANUFACTURING CO., LTD., TOKYO (JP)

(21) Appl. No.: 12/908,542

(22) Filed: Oct. 20, 2010

(30) Foreign Application Priority Data
Oct. 22, 2009 (JP) 2009-242975

(51) Int. Cl. H01L 29/417; H01L 21/8222

(52) U.S. Cl. 257/565; 438/309; 257/E21.608; 257/E29.114

(57) ABSTRACT

A bipolar semiconductor device includes a collector region that is an n-type low-resistance layer formed in one surface of a semiconductor crystal substrate, an n-type first high-resistance region on the collector region, a p-type base region on the first high-resistance region, an n-type low-resistance emitter region that is formed in another surface of the semiconductor crystal substrate, an n-type second high-resistance region between the emitter region and the base region so as to contact the emitter region, an n-type recombination suppressing region around the second high-resistance region so as to adjoin the second high-resistance region, and a p-type low-resistance base contact region which is provided so as to adjoin the recombination suppressing region, and which contacts the base region. Each of doping concentrations of the second high-resistance region and the recombination suppressing region is equal to or lower than 1×10¹⁷ cm⁻³.

### CROSS REFERENCE TO RELATED APPLICATION

This application claims the foreign priority benefit under Title 35, United States Code, §119(a)-(d) of Japanese Patent Application No. 2009-242975, filed on Oct. 22, 2009 in the Japan Patent Office, the disclosure of which is herein incorporated by reference in its entirety.

### BACKGROUND OF THE INVENTION

1. Field of the Invention

The present invention relates to a bipolar semiconductor device that is a junction device and a method of producing the same, and more particularly, a bipolar semiconductor device that is suitable for suppressing recombination of an electron with a hole in an emitter-base semiconductor surface and for increasing a current amplification factor, and a method of producing the same.

2. Description of the Related Art

Semiconductor silicon carbide (SiC) has a larger bandgap energy than silicon widely used in devices. Therefore, the semiconductor silicon carbide is suitable for a high voltage operation, a high power operation, and a high temperature operation, and an application to, for example, power devices is thus expected. The structure of SiC power devices actively researched and developed so far is mainly classified into a MOS device and a junction device (a bipolar transistor, a field-effect transistor, and a static induction transistor).

Illustrative SiC bipolar transistor reported so far will be explained below.

Typical example of such a bipolar transistor is disclosed in, for example, J. Zhang et al., “High Power (500V-70 A) and High Gain (44-47) 4H—SiC Bipolar Junction Transistors”, Materials Science Forum Vols. 457-460 (2004), pp. 1149-1152. This bipolar transistor has an n-type high resistance region, a p-type base region, and an n⁺-type emitter region laminated in this order on a low-resistance n⁺-type 4H—SiC substrate with a (0001) surface offset by eight degrees, and the emitter region includes plural long and thin regions. Electrodes are formed on the emitter region, the base region, and a collector region in order to provide electrical connections to the exterior.

FIG. 11 is a cross-sectional exemplary diagram of the bipolar transistor disclosed in the foregoing document. A bipolar transistor 100 includes a collector region 101 that is an n-type low-resistance layer, an n-type high-resistance region 102, a base region 103 that is a p-type region, an emitter region 104 that is an n-type low-resistance region, a base contact region 105 which surrounds the emitter region 104 and which is a p-type low-resistance region, a collector electrode 106, a base electrode 107, an emitter electrode 108, and a surface protection film 109.

An explanation will be given of an operation of a typical bipolar transistor with reference to FIG. 12. In FIG. 12, the same structural element as that shown in FIG. 11 will be denoted by the same reference numeral. Also, the surface protection film 109 which does not directly relate to the explanation for the operation will be omitted. A main current is an electron current indicated by an arrow 110 flowing from the emitter region 104 to the collector region 101, and the on/off state of such a current is controlled by a signal applied to the base electrode 107. At this time, the direction of the current is from the collector region 101 to the emitter region 104. When a voltage between the base electrode 107 and the emitter electrode 108 is equal to or smaller than 0 V, the bipolar transistor is in an off state, and when a positive voltage is applied between the base electrode 107 and the emitter electrode 108, the bipolar transistor makes transitions of its state to an on state. In the on state, a pn junction formed between the base electrode 107 and the emitter electrode 108 is subjected to a forward biasing, so that a hole current flows into the emitter region 104 from the base region 103.

It is desirable to control more main currents by less base currents in order to cause the bipolar transistor to operate highly efficiently. Hence, a current amplification factor (=a main current/a base current) is an important parameter. One of the factors that decreases the current amplification factor is a recombination state in a semiconductor surface exemplarily indicated by x marks denoted with a reference 111 in FIG. 12. Multiple surface states originating from uncombined atoms, crystal fault, etc., are present in the surface of the semiconductor. According to silicon, it is possible to produce a silicon-oxide film interface which has little surface states and which thus does not negatively affect to the device characteristics by thermal oxidation. On the other hand, in the case of SiC, it is currently difficult to sufficiently reduce the surface state density through thermal oxidation and a following heat treatment (POA: Post Oxidation Anneal), etc. Such surface states act as recombination states. Accordingly, as is exemplarily illustrated in FIG. 12, when the bipolar transistor is in an on state, at a part where multiple recombination states 111 by surface states of the surface of the base region 103 are present, holes 112 in the base region 103 and electrons 113 injected from the emitter region 104 coexist. This accelerates recombination of the hole and the electron (which is indicated by arrows 115, 116), and an ineffective base current that does not contribute to the operation of the device flows, resulting in reduction of the current amplification factor.

In order to reduce such recombination of an electron and a hole, following prior art are proposed. According to JP2006-351621A, an n-type semiconductor layer and a p-type recombination suppressing layer are provided on an SiC surface between a base and an emitter, thereby suppressing recombination of an electron and a hole in the SiC surface.

According to JP2009-54931A (see paragraph 0038 and FIGS. 1 and 8), a low-concentration emitter having a lower dopant concentration than that of an emitter is arranged between the emitter and a base, and a distance between the emitter and a base contact region is set to be equal to or longer than the diffusion length of an electron in the base, thereby improving the current amplification factor.

According to JP2007-173841A (see paragraph 0052), the thickness of an n-type silicon carbide protection layer and the dopant concentrations thereof are selected in such a way that the silicon carbide protection layer is completely depleted by a zero device biasing by an intrinsic voltage that is approximately 2.7 V generated at the pn junction between the n-type silicon carbide protection layer and a p-type base layer, thereby aiding reduction or suppression of a surface combination.

According to JP2006-351621A, however, an ion injection process is requisite in order to form the recombination suppressing layer, so that the production process becomes complex.

Also, according to JP2009-54931A, the recombination suppressing semiconductor region disclosed in the embodiment has a donor concentration of 3×10¹⁷ cm⁻³, and has a thickness of 50 nm. This recombination suppressing semiconductor region is formed by etching the emitter layer having a two-layer structure with different concentrations. In those layers, the lower emitter layer that serves as the recombination suppressing semiconductor region (the first emitter layer formed of a low-concentration n-type SiC) has a donor concentration of 3×10¹⁷ cm⁻³, and has a thickness of 100 nm. Moreover, the upper emitter layer (the second emitter layer formed of a high-concentration n-type SiC, i.e., a normal emitter) has a donor concentration of 1×10¹⁹ cm⁻³, and has a thickness of 1 μm (=1000 nm). In an etching process, it is extremely difficult to etch the emitter layer of 1100 nm and to produce the recombination suppressing semiconductor layer with a thickness of 50 nm with a good controllability. Also, because the lower emitter layer that serves as the recombination suppressing semiconductor region has the donor concentration which is high on some level (3×10¹⁷ cm⁻³), when a semiconductor device is in an off state in which no bias is applied between the base and the emitter, the recombination suppressing semiconductor region is depleted, but when the semiconductor device is in an on state in which a forward bias is applied between the base and the emitter which is most important, such recombination suppressing semiconductor region is not completely depleted, a sufficient recombination suppressing effect cannot be obtained. Note that JP2009-54931A does not disclose or suggest an appropriate donor concentration of the recombination suppressing semiconductor region.

According to JP2007-173841A, it is based on a condition in which the silicon carbide protection layer is completely depleted by a zero device biasing in order to suppress recombination, but it is insufficient to suppress recombination unless such a layer is completely depleted in a forward biasing condition. In an embodiment of JP2007-173841A, it is disclosed that the silicon carbide protection layer is capable of having an n-type doping concentration up to 1×10¹⁶ cm⁻³ at maximum when the thickness is approximately 0.5 μm, and in another embodiment, an n-type doping concentration up to 8×10¹⁴ cm⁻³ at maximum when the thickness is approximately 2 μm. In such cases, the silicon carbide protection layer can be depleted by zero biasing, but is not depleted in a forward biasing condition, so that it is difficult to increase the current amplification factor. Moreover, in order to form the silicon carbide protection layer, it is necessary to carry out an epitaxial growth after an emitter mesa is formed, which makes the process complex, so that the yield decreases and the silicon carbide semiconductor device becomes large in size, thereby making high-density integration difficult.

### SUMMARY OF THE INVENTION

The present invention may provide a bipolar semiconductor device which can be produced at a high yield through a simple production process and has a high current amplification factor, and a method of producing the same.

A first aspect of the present invention provides a bipolar semiconductor device comprising: a semiconductor crystal substrate comprising:

a collector region comprising a low-resistance layer of a first conductive type formed in one surface of the semiconductor crystal substrate;

a first high-resistance region of the first conductive type on the collector region;

a low-resistance base region of a second conductive type on the first high-resistance region;

a low-resistance emitter region of the first conductive type formed in another surface of the semiconductor crystal substrate;

a second high-resistance region of the first conductive type between the emitter region and the base region, contacting the emitter region;

a high-resistance recombination suppressing region of the first conductive type between the emitter region and the base region around the second high-resistance region, adjoining the second high-resistance region; and

a low-resistance base contact region of the second conductive type, adjoining the recombination suppressing region, contacting the base region. Each of doping concentrations of the second high-resistance region and the recombination suppressing region is equal to or lower than 1×10¹⁷ cm⁻³.

According to the foregoing structure, the bipolar semiconductor device includes the first conductive type second high-resistance region and the recombination suppressing region both of which are arranged between the emitter region and the base region and which have respective doping concentration set to be an appropriate value, so that a high current amplification factor can be obtained. Also, because the doping concentration is set to be an appropriate value, in comparison with a case in which the doping concentration is high, it is possible to produce the bipolar semiconductor device through a simple production process with a high yield.

A second aspect of the present invention based on the first aspect provides a bipolar semiconductor device, wherein each of doping concentrations of the first conductive type second high-resistance region and the recombination suppressing region is equal to or higher than 3×10¹⁶ cm⁻³ and a thickness of the recombination suppressing region is equal to or smaller than 0.1 μm. Such a bipolar semiconductor device can be produced through a simple production process.

A third aspect of the present invention based on the first aspect provides a bipolar semiconductor device, wherein each of doping concentrations of the first conductive type second high-resistance region and the recombination suppressing region exceeds 5×10¹⁵ cm⁻³ and is equal to or lower than 3×10¹⁶ cm⁻³, and a thickness of the recombination suppressing region is equal to or smaller than 0.2 μm. Such a bipolar semiconductor device can be produced through a simple production process.

A fourth aspect of the present invention based on the first aspect provides a bipolar semiconductor device, wherein each of doping concentrations of the first conductive type second high-resistance region and the recombination suppressing region is equal to or lower than 5×10¹⁵ cm⁻³ and a thickness of the recombination suppressing region is equal to or smaller than 0.4 μm. Such a bipolar semiconductor device can be produced through a simple production process.

A fifth aspect of the present invention provides a method of producing a bipolar semiconductor device comprising the steps of:

forming a first high-resistance layer of a first conductive type on a low-resistance semiconductor substrate of the first conductive type;

forming a low-resistance base region of a second conductive type;

forming a second high-resistance layer of the first conductive type that has a doping concentration equal to or lower than 1×10¹⁷ cm⁻³;

forming a low-resistance layer of the first conductive type;

partially etching the low-resistance layer and the second high-resistance layer to form an emitter region, and etching a surface of the second high-resistance layer to be exposed as a recombination suppressing region around the emitter region;

forming a low-resistance base contact region which adjoins the recombination suppressing region and which is joined to the base region;

forming a base electrode, an emitter electrode, and a collector electrode; and

forming an upper-layer electrode on a side of the base electrode side and the emitter electrode side.

According to the foregoing procedures, the bipolar semiconductor device production method can form the first conductive type second high-resistance layer with an appropriate doping concentration in the second-high-resistance-layer formation step, and can simultaneously form the recombination suppressing region by etching that forms the emitter region on the first conductive type second high-resistance layer in the emitter-region formation step. Also, because the doping concentration of the recombination suppressing region is set to be equal to or lower than 1×10¹⁷ cm⁻³, even if the recombination suppressing region is thickened to some level, an effect of suppressing recombination of an electron with a hole can be obtained. Accordingly, the allowable range of an etching depth can be set to be relatively large when the emitter region is formed. As a result, such a bipolar semiconductor device can be produced through a simple production process.

According to the bipolar semiconductor device of the present invention, a first conductive type recombination suppressing region is provided between a base contact region and an emitter region, and the doping concentration of the recombination suppressing region is sufficiently lowered, a thickness sufficient for production is secured, and the current amplification factor can be increased.

Also, according to the production method of the bipolar semiconductor device of the present invention, a recombination suppressing region is formed in such a way that a doping concentration is sufficiently lowered, while at the same time, a sufficient thickness is secured in order to suppress recombination of an electron and a hole in the recombination suppressing region, when an emitter region is formed, an allowable range of an etching depth can be set relatively large. Accordingly, it is possible to produce the bipolar semiconductor device through a simpler production process with a high yield being secured.

### BRIEF DESCRIPTION OF THE DRAWINGS

The object and features of the present invention will become more readily apparent from the following detailed description taken in conjunction with the accompanying drawings in which:

FIG. 1 is a cross-sectional view showing a part of a bipolar transistor according to an embodiment of the present invention;

FIG. 2 is a plan view showing the bipolar transistor of the embodiment of the present invention partially transparent;

FIG. 3 is an explanatory diagram for an operation of the bipolar transistor of the embodiment of the present invention;

FIG. 4 is a flowchart showing steps of producing the bipolar transistor of the embodiment of the present invention;

FIG. 5A is a cross-sectional view of a semiconductor crystal substrate in one of steps of producing the bipolar transistor of the embodiment of the present invention;

FIG. 5B is a cross-sectional view of the semiconductor crystal substrate in one of steps of producing the bipolar transistor of the embodiment of the present invention;

FIG. 5C is a cross-sectional view of the semiconductor crystal substrate in one of steps of producing the bipolar transistor of the embodiment of the present invention;

FIG. 5D is a cross-sectional view of the semiconductor crystal substrate in one of steps of producing the bipolar transistor of the embodiment of the present invention;

FIG. 6A is a cross-sectional view of the semiconductor crystal substrate in one of steps of producing the bipolar transistor of the embodiment of the present invention;

FIG. 6B is a cross-sectional view of the semiconductor crystal substrate in one of steps of producing the bipolar transistor of the embodiment of the present invention;

FIG. 6C is a cross-sectional view of the semiconductor crystal substrate in one of steps of producing the bipolar transistor of the embodiment of the present invention;

FIG. 7 is a graph showing a relationship between the doping concentration of a second high-resistance layer and the thickness thereof in a bipolar transistor produced with the doping concentration of the second high-resistance layer and the thickness thereof being widely changed and a current amplification factor;

FIG. 8 is a graph showing the doping concentration of the second high-resistance layer and the thickness of a recombination suppressing region in a bipolar transistor produced through another scheme and a current amplification factor;

FIG. 9 is a graph showing a relationship between the doping concentration of a second high-resistance layer and the thickness of the recombination suppressing region in a bipolar transistor produced with the doping concentration of the second high-resistance layer and the thickness thereof being widely changed and a current amplification factor;

FIG. 10 is a graph showing a relationship between the doping concentration of a second high-resistance layer and the thickness thereof in a bipolar transistor produced with the doping concentration of the second high-resistance layer and the thickness thereof being widely changed;

FIG. 11 is a cross-sectional exemplary diagram for a conventional bipolar transistor; and

FIG. 12 is an explanatory diagram for an operation of the conventional bipolar transistor.

The same or corresponding elements or parts are designated with like references throughout the drawings.

### DETAILED DESCRIPTION OF THE INVENTION

A detailed explanation will be given of an embodiment of a bipolar semiconductor device of the present invention with reference to the accompanying drawings.

<Structure of Bipolar Transistor>

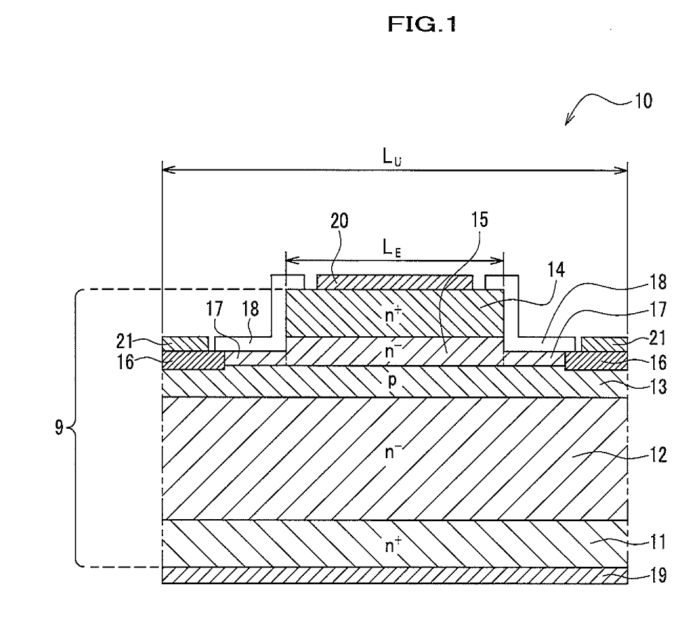

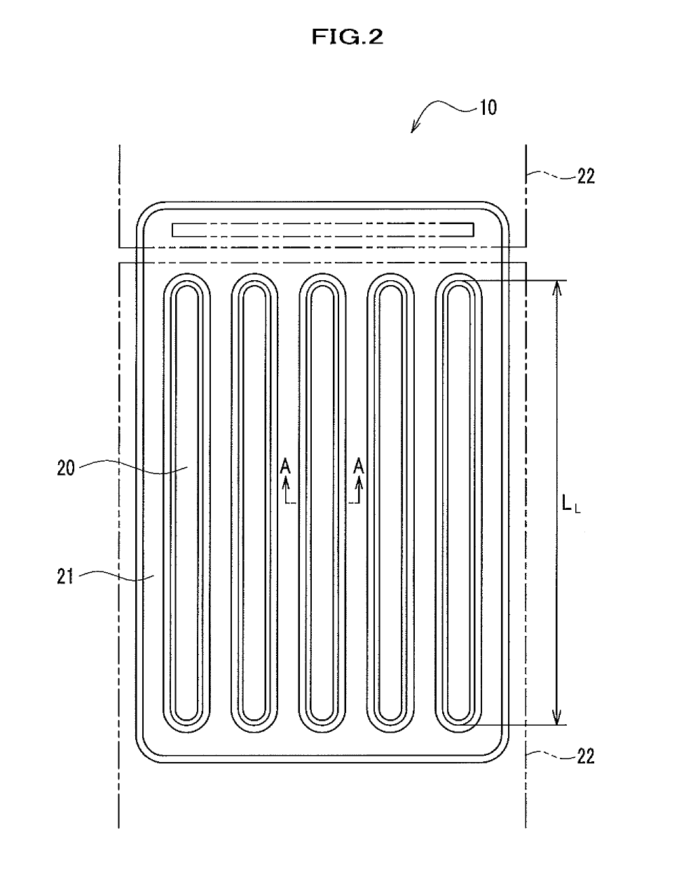

A bipolar transistor of the embodiment of the present invention will be explained as an example of the bipolar semiconductor device. A bipolar transistor 10 shown in FIGS. 1 and 2 includes a semiconductor crystal substrate 9 made of silicon carbide (SiC), and has five emitter electrodes 20 on the semiconductor crystal substrate 9. FIG. 1 shows a structure of a cross section along a line A-A in FIG. 2 in an enlarged manner.

As shown in FIG. 1, the bipolar transistor 10 has the semiconductor crystal substrate 9 including a collector region 11 that is an n-type (first conductive type) low-resistance layer (n⁺), an n-type first high-resistance (n⁻) region 12, a p-type (second conductive type) base region 13, an n-type low-resistance (n⁺) emitter region 14, an n-type second high-resistance region 15, an n-type high-resistance recombination suppressing region 17, and a low-resistance base contact region 16, and has a recombination suppressing film 18 formed of a thin film, such as a CVD oxide film and a CVD nitride film, a collector electrode 19, the emitter electrodes 20, and a base electrode 21.

Individual regions are laminated as follows in the semiconductor crystal substrate 9. The collector region 11 is formed in one face of the semiconductor crystal substrate 9. The n-type first high-resistance (n⁻) region 12 is provided on the collector region 11. The p-type base region 13 is provided on the n-type first high-resistance region 12. The n-type low-resistance (n⁺) emitter region 14 is formed in another face of the semiconductor crystal substrate 9. The n-type second high-resistance region 15 is arranged between the emitter region 14 and the base region 13, and contacts the emitter region 14. The n-type high-resistance recombination suppressing region 17 is arranged between the emitter region 14 and the base region 13, adjoins the second high-resistance region 15 and is provided therearound. The low-resistance base contact region 16 adjoins the recombination suppressing region 17, and contacts the base region 13.

The recombination suppressing film 18 is formed on a surface of an SiC crystal between the base contact region 16 and the emitter region 14. The collector electrode 19 contacts the collector region 11. The emitter electrodes 20 contact the emitter region 14. The base electrode 21 contacts the base contact region 16. As shown in FIG. 2, an upper-layer electrode 22 (omitted in FIG. 1) is provided on the emitter electrodes 20 and on the base electrode 21.

According to this bipolar transistor 10, the n-type second high-resistance region 15 and the n-type high-resistance recombination suppressing region 17 have respective doping concentrations set to be equal to or less than 1×10¹⁷ cm⁻³ which is a low concentration. That is, regarding a layer for suppressing recombination between the emitter and the base, the doping concentration is set to be equal both in the n-type second high-resistance region 15 arranged right below the emitter region 14 and in the n-type high-resistance recombination suppressing region 17 arranged outwardly therearound. As explained above, individual regions have the same concentration range and the doping concentration of each region is equal to or smaller than 1×10¹⁷ cm⁻³ which is a low concentration. Accordingly, in a condition in which forward biasing is applied between the base and the emitter, the n-type high-resistance recombination suppressing region 17 can be depleted. In the present embodiment, when the doping concentration is larger than 1×10¹⁷ cm⁻³, it is called a high concentration.

Also, according to the bipolar transistor 10, in the semiconductor crystal substrate 9, the n-type first high-resistance region 12, the n-type second high-resistance region 15, and the n-type high-resistance recombination suppressing region 17 are all n-type high-resistance regions, and those regions are simply referred to as the first high-resistance region 12, the second high-resistance region 15, and the recombination region 17, respectively. Also, because when the doping concentration is set to be high, the electrical resistance or the like decreases, in this embodiment, as an example, a high-resistance region (a region with a high relative resistance) has a doping concentration of equal to or smaller than 1×10¹⁷ cm⁻³ which is a low concentration, and a low-resistance region has a doping concentration of larger than 1×10¹⁷ cm⁻³.

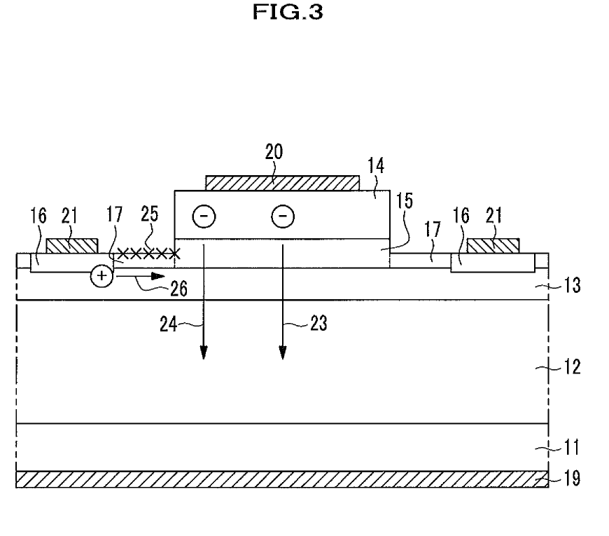

With reference to FIG. 3, an operation of the bipolar transistor 10 will be explained. In FIG. 3, the same structural elements explained in FIG. 1 will be denoted by the same reference numerals, respectively. Also, in FIG. 3, the recombination suppressing film 18 which does not directly relate to the explanation for the operation will be omitted.

A main current is an electron current (indicated by arrows 23, 24) flowing from the emitter region 14 to the collector region 11, and the on/off operation of the bipolar transistor 10 is controlled by a signal applied to the base electrode 21. At this time, the direction of the current is from the collector region 11 to the emitter region 14. When a voltage across the base electrode 21 and the emitter electrodes 20 is equal to or lower than 0 V, the bipolar transistor 10 is in an off state, and when a voltage is applied across the base electrode 21 and the emitter electrodes 20, the bipolar transistor 10 transitions its state to an on state. In the on state, a pn junction formed between the base electrode 21 and respective emitter electrodes 20 is subjected to forward biasing, so that a hole current 26 starts flowing from the base region 13 to the emitter region 14.

According to the conventional structure shown in FIG. 12, at a part where a number of recombination states of the surface of the base region 103 are present in an on state, i.e., a portion between the base contact region 105 and the emitter region 104, holes 112 of the base region 103 and electrons 113 injected from the emitter region 104 coexist. Accordingly, recombination (indicated by arrows 115, 116) of the electron with the hole is promoted, and an ineffective base current which does not contribute to the device operation flows, resulting in reduction of the current amplification factor. According to the structure of this embodiment of the present invention, however, as shown in FIGS. 1 and 3, because the recombination suppressing region 17 with a low doping concentration is provided between the base contact region 16 and the emitter region 14, holes of the base region 13 and the electrons injected from the emitter region 14 are moved apart from the surface of the base region 13 (indicated by the marks of “x” denoted with the reference numeral 25 in FIG. 3), thereby suppressing recombination of the hole with the electron. As a result, the number of holes recombined decreases, and the current amplification factor increases. Therefore, the device characteristics can be improved.

The same effect may be accomplished by JP2009-54931A, but the doping concentration (donor concentration) of the recombination suppressing semiconductor region disclosed in JP2009-54931A is 3×10¹⁷ cm⁻³, which is extremely larger than the doping concentration (equal to or lower than 1×10¹⁷ cm⁻³) of the recombination suppressing region 17 of the bipolar transistor 10 of the embodiment of the present invention. In such a case, recombination of an electron with a hole cannot be suppressed unless the recombination suppressing semiconductor region is formed so as to be extremely thin (according to JP2009-54931A, 50 nm). Because the etching depth in a step of forming an emitter by dry etching is approximately 1 μm, it is extremely difficult to obtain a depth precision in a 50-nm order.

On the other hand, according to the bipolar transistor 10 of this embodiment of the present invention, the recombination suppressing region 17 has a doping concentration of equal to or lower than 1×10¹⁷ cm⁻³, so that if the thickness of the recombination suppressing region 17 is set to be approximately 100 nm (=0.1 μm), an effect of suppressing recombination of an electron with a hole can be obtained. This is because lowering of the doping concentration facilitates the recombination suppressing region 17 to be depleted, and the whole recombination suppressing region 17 can be depleted even if the thickness is large to some level.

Also, according to this embodiment, the value of the doping concentration and the thickness thereof of the recombination suppressing region 17 are set in such a way that the recombination suppressing region 17 is depleted in all operational ranges of the device. In bipolar transistors, a condition in which expansion of a depletion layer becomes difficult in the recombination suppressing region 17 is a condition in which the device subjected to a forward biasing between the base and the emitter where recombination of an electron with a hole becomes a problem mostly is turned on. In this condition, a hole flows from the base to the emitter, and an electron flows from the emitter to the collector, so that a recombination of an electron with a hole is likely to occur in a semiconductor surface between the base and the emitter. Also, a higher current amplification factor is requisite in an on state. Accordingly, the doping concentration of the recombination suppressing region 17 is set in order to ensure sufficient expansion of the depletion layer even if a forward biasing is applied between the base and the emitter when a recombination of an electron with a hole becomes a problem with the bipolar transistor 10 being in an on state. This is a remarkable difference from JP2009-54931A and JP2007-173841A. This makes it possible for the bipolar transistor 10 to obtain a high current amplification factor across wide operational ranges.

The structure of the bipolar transistor 10 according to this embodiment of the present invention will be further explained with reference to FIG. 1. The semiconductor crystal substrate is a low-resistance n-type 4H—SiC substrate that is offset by 8 degrees from a (0001) surface, and in this transistor, this substrate serves as the collector region 11.

The n-type first high-resistance region 12 on the substrate (the collector region 11) is a layer for blocking a high voltage applied to the emitter electrodes 20 and the collector electrode 19. In this embodiment, in order to block a voltage equal to or higher than 600 V, a thickness of the first high-resistance region 12 is set to be approximately 10 μm, and the doping concentration thereof is set to be 5×10¹⁵ to 1×10¹⁶ cm⁻³.

The p-type base region 13 on the n-type first high-resistance region 12 has a thickness and a doping concentration set in such a manner as not to be depleted when a high voltage is applied between the emitter electrodes 20 and the collector electrode 19. For example, the thickness is set to be 0.1 to 1.0 μm, and the doping concentration is set to be 1×10¹⁷ to 1×10¹⁸ cm⁻³.

Provided on the base region 13 is the low-resistance n-type emitter region 14 having a thickness of 0.5 to 2.0 μm and a doping concentration of 1 to 5×10¹⁹ cm⁻³ with the n-type second high-resistance region 15 having a thickness of 0.1 to 0.6 μm and a doping concentration of 1×10¹⁷ cm⁻³ intervening.

The emitter region 14 is a region joined with the emitter electrodes 20 shown in FIG. 2, and is separated into plural long and thin pieces facing with respective emitter electrodes 20. The separated piece is provided with the base electrode 21. Regarding the dimension of a piece of emitter region 14, a width indicated by LE in FIG. 1 is 10 to several 10 μm, and a length indicated by LL in FIG. 2 is 100 to several 1000 μm. A cycle (indicated by Lu in FIG. 1) of unit device including the base electrode 21 and one emitter electrode 20 is 20 to several 10 μm.

<How to Produce Bipolar Transistor>

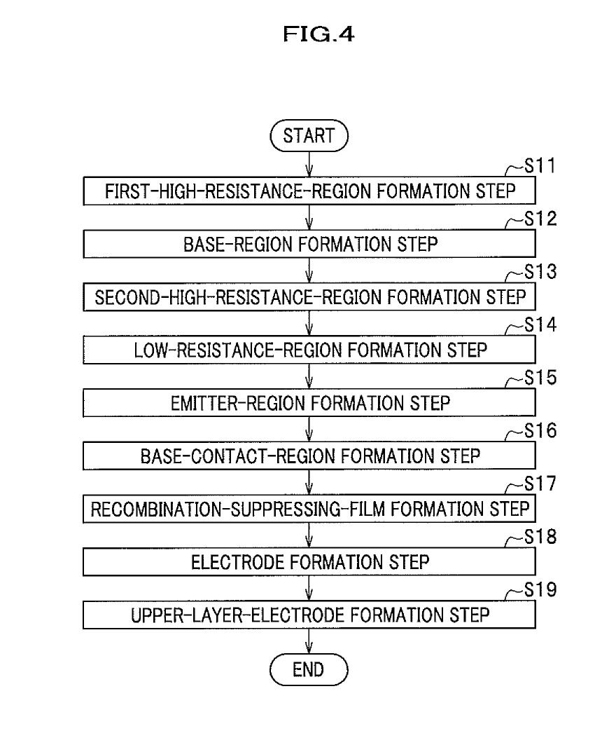

Next, with reference to FIGS. 4 to 6C (and FIGS. 1 and 2, as needed), an explanation will be given of how to produce the bipolar transistor 10 according to this embodiment of the present invention. As shown in FIG. 4, a method of producing the bipolar transistor includes a first-high-resistance-layer formation step (step S11), a base-region formation step (step S12), a second-high-resistance-layer formation step (step S13), a low-resistance-layer formation step (step S14), an emitter-region formation step (step S15), a base-contact-region formation step (step S16), a recombination-suppressing-film formation step (step S17), an electrode formation step (step S18), and an upper-layer-electrode formation step (step S19).

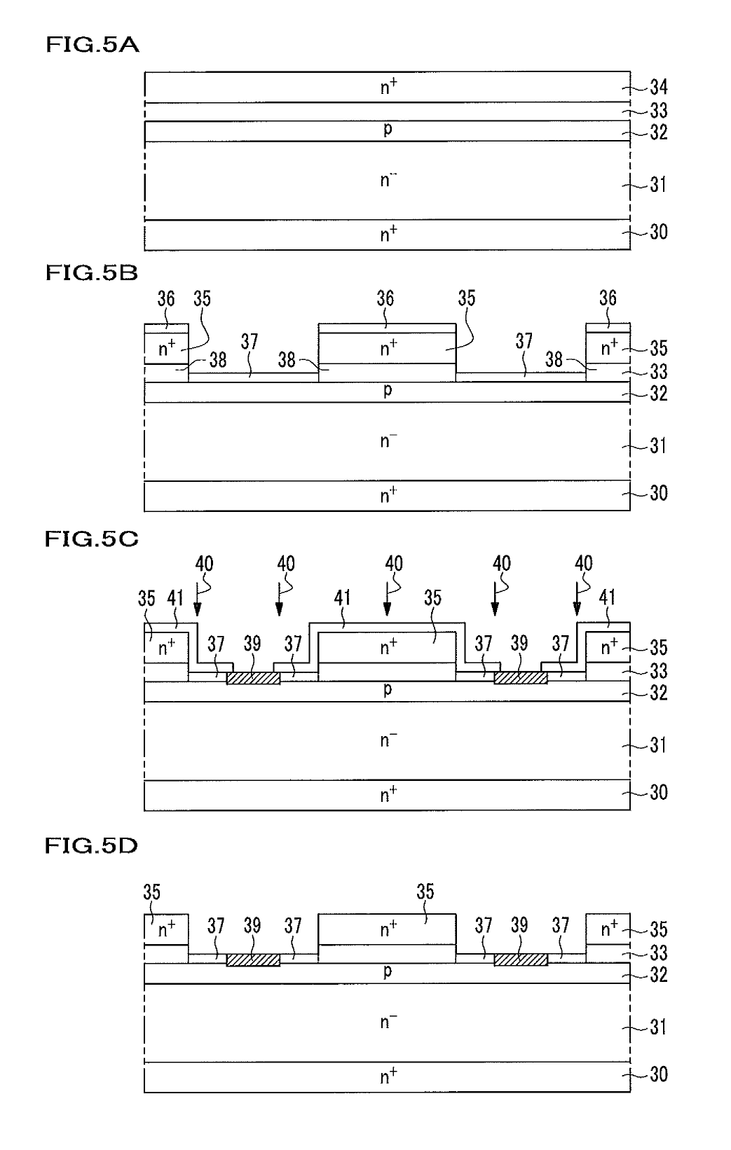

The first-high-resistance-layer formation step (step S11) is a step of forming an n-type first high-resistance layer 31 on an n-type (the first conductive type) low-resistance semiconductor substrate (an SiC high-concentration n-type substrate 30). In this step, as shown in FIG. 5A, an SiC layer where nitrogen is doped as a dopant at a doping concentration of 1×10¹⁶ cm⁻³ with a thickness of 10 μm is formed as an n-type first high-resistance layer 31 on the SiC high-concentration n-type substrate 30 by, for example, an epitaxial growth technique.

The base-region formation step (step S12) is a step of forming a p-type (the second conductive type) low-resistance base region 32. In this step, an SiC layer including aluminum as a dopant at a concentration of 1×10¹⁷ to 1×10¹⁸ cm⁻³ with a thickness of 0.1 to 1.0 μm is grown as a base region 32 by, for example, an epitaxial growth technique.

The second-high-resistance-layer formation step (step S13) is a step of forming an n-type second high-resistance layer 33. In this step, an SiC layer where nitrogen is doped as a dopant at a doping concentration of equal to or lower than 1.0×10¹⁷ cm⁻³ with a thickness of 0.1 to 0.6 μm is formed by, for example, an epitaxial growth technique.

The low-resistance-layer formation step (step S14) is a step of forming an n-type low-resistance layer 34. In this step, the n-type low-resistance layer 34 that is an SiC layer where nitrogen is doped as a dopant at a doping concentration of 1 to 5×10¹⁹ cm⁻³ at a thickness of 0.5 to 2.0 μm is formed on the n-type second high-resistance layer 33 that is an SiC by, for example, an epitaxial growth technique.

The emitter-region formation step (step S15) is a step of forming an emitter region 35 by partially etching the n-type low-resistance layer 34 and the second high-resistance layer 33, and of making the surface of the n-type second high-resistance layer 33 exposed as a recombination suppressing region 37 around the emitter region 35 by etching. The emitter region 35 is a part of the n-type low-resistance layer 34 left by etching. Also, the n-type second high-resistance layer 33 which contacts the lower part of the emitter region 35 and which is left by etching becomes a second high-resistance region 38.

In this step, as shown in FIG. 5B, in order to separate the emitter region into plural pieces, the n-type low-resistance layer 34 and the n-type second high-resistance layer 33 are partially etched. For example, a CVD (Chemical Vapor Deposition) silicon oxide film is used as an etching mask 36, a resist pattern is formed through a photolithography step, the CVD silicon oxide film is etched by, for example, RIE (Reactive Ion Etching), and the SiC is further etched using the CVD silicon oxide film as a mask. For etching of the SiC, RIE with SF₆, etc., can be applied.

The etching depth is roughly set to be a half of a total of the thickness of the n-type low-resistance layer 34 and the n-type second high-resistance layer 33. For example, when the thickness of the n-type low-resistance layer 34 is 1.0 μm, and the thickness of the n-type second high-resistance layer 33 is 0.2 μm, the etching depth becomes 1.1 μm. In this embodiment, the concentration of the n-type second high-resistance layer 33 and the thickness thereof are set so that an etching end face in the emitter-region formation step (step S15) can be at any part in the n-type second high-resistance layer 33. Accordingly, when the etching depth is 1.1 μm, the allowable range of variation in etching depth is 1.0 to 1.2 μm, and an etching error of ±10% is allowed. When the thickness of the n-type second high-resistance layer 33 is 0.2 μm, the thickness of the second high-resistance region 38 is also 0.2 μm. In this case, a target value of the thickness of the recombination suppressing region 37 is 0.1 μm, and the allowable range of variation in thickness is approximately 0 to 0.2 μm.

The base-contact-region formation step (step S16) is a step of forming a low-resistance base contact region 39 which adjoins the recombination suppressing region 37 and which contacts the base region 32. In this step, as shown in FIG. 5C, in order to form the base contact region 39 contacting the base region 32, selective ion injection is performed on a portion where a base electrode is formed. This step makes the doping concentration of the semiconductor surface high in order to reduce a contact resistance between a metal electrode and a semiconductor. An example of the material for a mask 41 for an ion injection indicated by an arrow 40 is a CVD silicon oxide film. The ion kind is aluminum. In order to obtain an ion injection depth of approximately 0.2 to 0.4 μm, multistage injection with a maximum injection energy of approximately 300 keV is performed. The injection amount is set so that the doping concentration becomes approximately 1×10¹⁸ to 1×10¹⁹ cm⁻³. After ion injection, the mask 41 is etched and eliminated.

Next, as shown in FIG. 5D, after ion injection, in order to make the injected ions electrically active in the semiconductor and to eliminate crystal faults produced by ion injection, an activation heating process is executed. In this heating process, for example, a high-frequency heating process furnace is used, and a heating process is executed under a high temperature circumstance of 1700 to 1800° C. for approximately 10 minutes. An atmosphere gas which is argon is used.

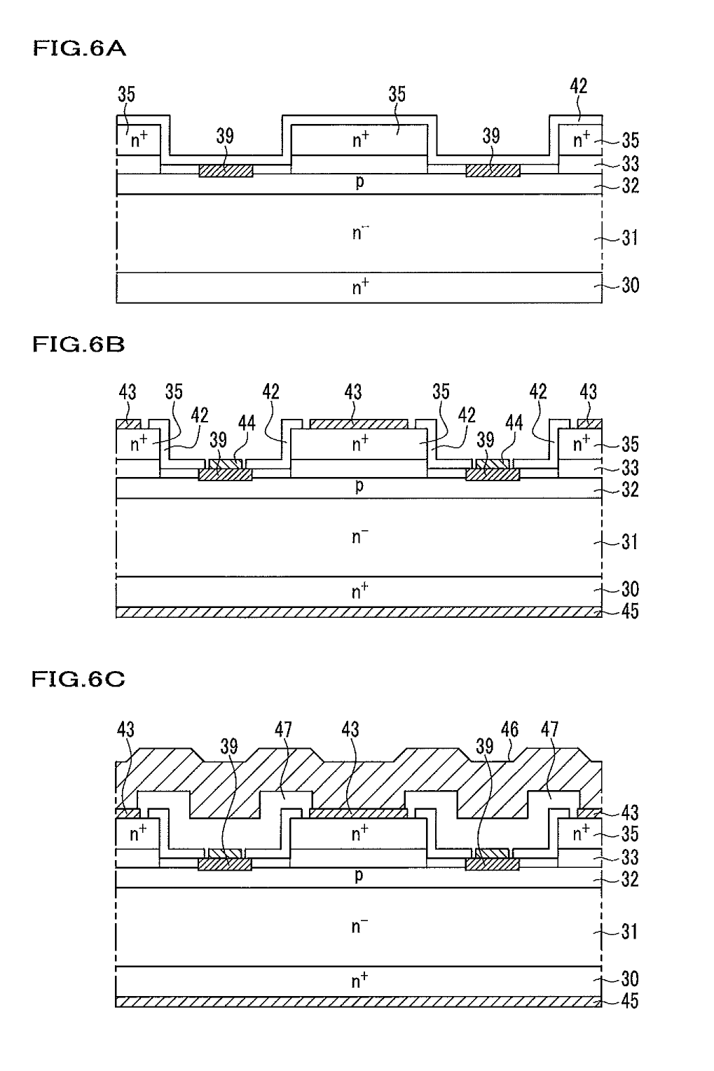

The recombination-suppressing-film formation step (step S17) is a step of forming a recombination suppressing film 42 on the semiconductor crystal surface between the base contact region 39 and the emitter region 35. In this step, first, in order to eliminate a surface layer formed by ion injection and the activation heating process, thermal oxidation is performed, and sacrificial oxidation is then performed in order to eliminate an oxide film formed by thermal oxidation. Oxidation conditions are, for example, 1100° C., 20 hours in dry oxygen. Hydrofluoric acid is used for elimination of the oxide film. After sacrificial oxidation, thermal oxidation is performed again, and an oxide film is formed. Thereafter, a heating process (POA: Post Oxidation Anneal) for reducing the impurity level of the interface between the SiC and the oxide film is performed. POA is performed under a high temperature atmosphere like 800 to 1300° C. under a hydrogen or nitride oxide (NO, N₂O) atmosphere. After POA, the recombination suppressing film 42 comprising a thin film, such as a CVD oxide film or a CVD nitride film, is formed (see FIG. 6A).

The electrode formation step (step S18) is a step of forming a base electrode, an emitter electrode, and a collector electrode. In this step, as shown in FIG. 6B, an emitter electrode 43, a base electrode 44, and a collector electrode 45 contacting the emitter region 35, the base contact region 39, and the SiC high-concentration n-type substrate 30 (collector region), respectively, are formed. Metals used for the emitter electrode 43 and the collector electrode 45 are, for example, nickel, titanium, and a metal used for the base electrode 44 is, for example, a titanium/aluminum (TiAl) alloy. Each electrode is formed by vapor deposition, sputtering, etc., and for pattern formation, a photolithography step, dry etching, wet etching, a lift-off technique can be applied. Also, after the electrodes are formed, a heating process is executed in order to reduce respective contact resistance between the metal used for the electrode and each of the emitter region 35, the base contact region 39, and the SiC high-concentration n-type substrate 30 serving as the collector region. Heating conditions are, for example, 800 to 1000° C., and 10 to 30 minutes.

The upper-layer-electrode formation step (step S19) is a step of forming the upper-layer electrode on the base electrode 44 and the emitter electrode 43. In this step, as shown in FIG. 6C, an upper-layer electrode 46 connected to the whole emitter electrodes 43 separated is formed. An interlayer film 47 like a CVD oxide film is formed, and the CVD oxide film on a part corresponding to the emitter electrode 43 and a part corresponding to the base electrode 44 by a photolithography step and etching to make the emitter electrode 43 and the base electrode 44 exposed. Thereafter, the upper-layer electrode 46 is deposited. A material of the upper-layer electrode 46 is aluminum (FIG. 6C shows a cross section of a part where the emitter electrode 43 is exposed).

Through those steps, the high-performance bipolar transistor shown in FIGS. 1 and 2 can be produced.

<Specific Examples of Bipolar Transistor in Test Production>

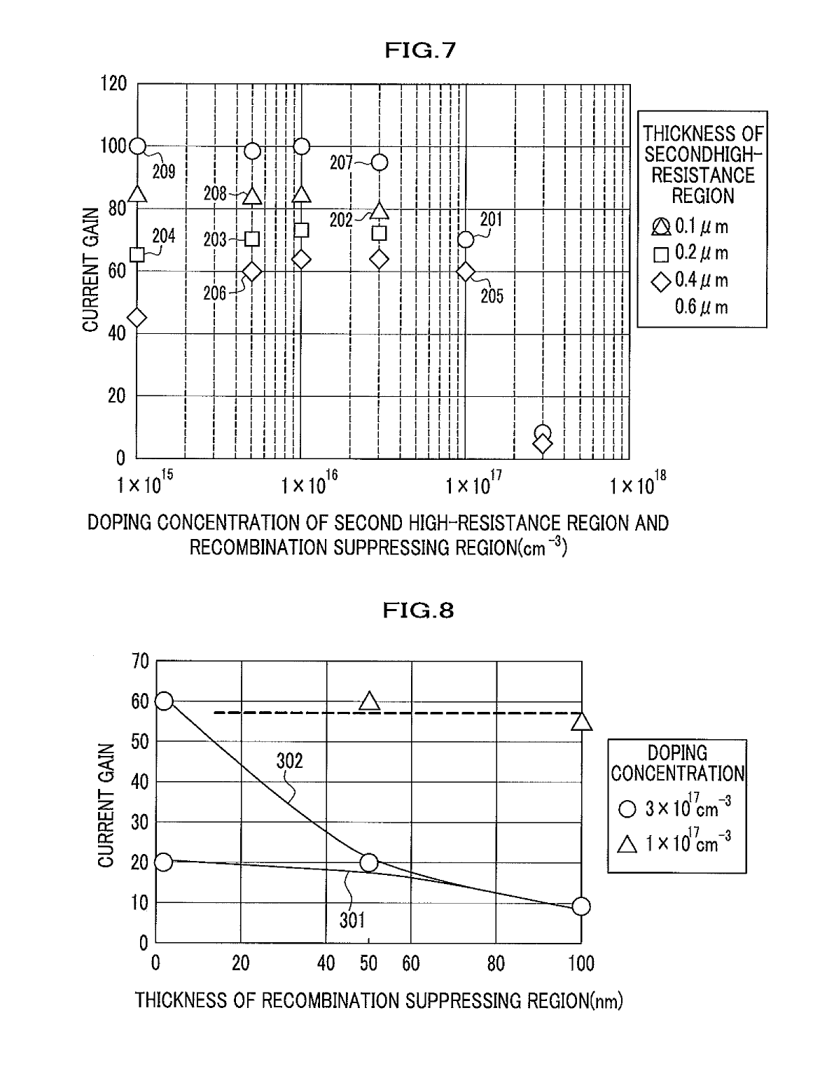

In the bipolar transistor 10 shown in FIG. 1, the doping concentration of the second high-resistance region 15 and that of the recombination suppressing region 17, the thickness of the second high-resistance region 15 and that of the recombination suppressing region 17 were widely changed, and plural bipolar transistors 10 were produced as test samples. Respective characteristics of current amplification factors of sample bipolar transistors 10 are shown in FIG. 7.

A horizontal axis of the graph in FIG. 7 represents respective doping concentrations of the second high-resistance region and the recombination suppressing region (hereinafter, referred to as a doping concentration of the second high-resistance layer), and a vertical axis represents a current amplification factor. In this example, respective bipolar transistors having the second high-resistance region 15 with a thickness of 0.1 μm (indicated by a circle in FIG. 7), 0.2 μm (indicated by a triangle in the figure), 0.4 μm (indicated by a rectangle in the figure), and 0.6 μm (indicated by a rhombic symbol in the figure) were produced as test samples.

The graph of FIG. 7 shows a total of 20 samples. Among 17 samples which had a current amplification factor equal to or higher than 50, nine samples were denoted by reference numerals 201 to 209, and those are shown in table 1 as examples 201 to 209 together with a thickness of the recombination suppressing region 17. It is preferable that the value of the current amplification factor should be equal to or higher than 50, and the higher such a value is like equal to or higher than 100, the more it is preferable. The value of the current amplification factor depends on the application of the bipolar transistor, but as a minimum level for practical use, at least 35 is requisite. Hence, in this embodiment, the performance of an example having the current amplification factor equal to or higher than 50 was determined as a good performance.

TABLE 1

| | Second high- | | Recombination | | |
|---|---|---|---|---|---|
| | resistance region | | suppressing region | | Current |
| | Thick- | Doping | Thick- | Doping | amplifi- |
| | ness | concentration | ness | concentration | cation |
| | [μm] | [cm⁻³] | [μm] | [cm⁻³] | factor |
| Ex 201 | 0.1 | 1.0 × 10¹⁷ | 0.1 | 1.0 × 10¹⁷ | 70 |
| Ex 202 | 0.2 | 3.0 × 10¹⁶ | 0.2 | 3.0 × 10¹⁶ | 80 |
| Ex 203 | 0.4 | 5.0 × 10¹⁵ | 0.4 | 5.0 × 10¹⁵ | 70 |
| Ex 204 | 0.4 | 1.0 × 10¹⁵ | 0.4 | 1.0 × 10¹⁵ | 65 |
| Ex 205 | 0.6 | 1.0 × 10¹⁷ | 0.1 | 1.0 × 10¹⁷ | 60 |
| Ex 206 | 0.6 | 5.0 × 10¹⁵ | 0.4 | 5.0 × 10¹⁵ | 60 |
| Ex 207 | 0.1 | 3.0 × 10¹⁶ | 0.1 | 3.0 × 10¹⁶ | 95 |
| Ex 208 | 0.2 | 5.0 × 10¹⁵ | 0.2 | 5.0 × 10¹⁵ | 85 |
| Ex 209 | 0.1 | 1.0 × 10¹⁵ | 0.1 | 1.0 × 10¹⁵ | 100 |

As shown in the graph of FIG. 7, first, the current amplification factor largely changes depending on the doping concentration of the second high-resistance layer 15. Second, the current amplification factor largely changes depending on the thickness of the second high-resistance region 15. Third, the thickness of the recombination suppressing region 17 largely affects the current amplification factor as discussed later.

<Relationship Between Doping Concentration of Second High-Resistance Layer and Current Amplification Factor>

First, an explanation will be given of a relationship between the doping concentration of the second high-resistance layer and the current amplification factor. When the doping concentration of the second high-resistance layer is increased, the injection efficiency of the emitter (=(the number of electrons injected from the emitter to the base per unit time)÷(the number of holes injected from the base to the emitter)) increases. Therefore, the current amplification factor increases. For example, the examples (Ex) 204 and 203 were produced as test samples with the same thickness of each region but the doping concentration was changed. According to those examples, the higher the doping concentration is (example 203), the higher the current amplification factor becomes.

On the other hand, increasing of the doping concentration of the second high-resistance layer results in increasing of the doping concentration of the recombination suppressing region 17. Accordingly, recombination of an electron with a hole in the SiC surface of the recombination suppressing region 17 becomes active, resulting in decreasing of the current amplification factor. For example, the examples 207 and 201 were produced as test samples with the same thickness of each region. According to those examples, the higher the doping concentration is (example 201), the lower the current amplification factor becomes.

As explained above, if the doping concentration of the second high-resistance layer is too high or too low, it negatively affects the current amplification factor. Also, as will be discussed later, the doping concentration of the second high-resistance layer correlates with the thickness of the second high-resistance region 15 and that of the recombination suppressing region 17.

<Relationship Between Doping Concentration of Second High-Resistance Layer and Thickness of Recombination Suppressing Region>

At a right part from the center of the graph in FIG. 7, i.e., an area where the doping concentration of the second high-resistance layer is relatively high, it is important to make the thickness of the recombination suppressing region 17 thin in order to obtain the high current amplification factor. This is because when the doping concentration of the recombination suppressing region 17 (=the doping concentration of the second high-resistance layer) is relatively high, it is necessary to make the recombination suppressing region 17 thin to facilitate depletion of the recombination suppressing region 17.

<Relationship Between Thickness of Recombination Suppressing Region and Current Amplification Factor>

In the graph of FIG. 7, among the samples having the current amplification factor equal to or higher than 50, the maximum value of the doping concentration of the second high-resistance layer was 1×10¹⁷ cm⁻³ (examples 201 and 205). Accordingly, under a condition in which the doping concentration of the second high-resistance layer was fixed to be 1×10¹⁷ cm⁻³, some bipolar transistors were produced as test samples in order to research the relationship between the thickness of the recombination suppressing region 17 and the current amplification factor (examples 1 and 2). As comparative examples, bipolar transistors were produced under a condition in which the doping concentration of the second high-resistance layer was fixed to be 3×10¹⁷ cm⁻³ in order to research the relationship between the thickness of the recombination suppressing region 17 and the current amplification factor (comparative examples 1 to 3). A measurement result of each sample is shown in table 2 and a graph of FIG. 8. The thickness of the second high-resistance region 15 can be set accordingly within a range from 0.1 to 0.6 μm, but was set to be 0.2 μm in each sample.

TABLE 2

| | Second high- | | Recombination | | |
|---|---|---|---|---|---|
| | resistance region | | suppressing region | | |
| | | Doping | | Doping | Current |
| | Thick- | concentra- | Thick- | concentra- | amplifi- |
| | ness | tion | ness | tion | cation |
| | [μm] | [cm⁻³] | [μm] | [cm⁻³] | factor |
| Compar. Ex 1 | 0.2 | 3.0 × 10¹⁷ | 100 | 3.0 × 10¹⁷ | 9 |
| Compar. Ex 2 | 0.2 | 3.0 × 10¹⁶ | 50 | 3.0 × 10¹⁷ | 20 |
| Compar. Ex 3 | 0.2 | 3.0 × 10¹⁷ | ~0 | 3.0 × 10¹⁷ | 20 |
| Compar. Ex 4 | 0.2 | 3.0 × 10¹⁷ | ~0 | 3.0 × 10¹⁷ | 60 |
| Ex 1 | 0.2 | 1.0 × 10¹⁷ | 100 | 1.0 × 10¹⁷ | 54 |
| Ex 2 | 0.2 | 1.0 × 10¹⁷ | 50 | 1.0 × 10¹⁷ | 60 |

The horizontal axis of the graph in FIG. 8 represents a thickness (nm) of the recombination suppressing region and the vertical axis represents a current amplification factor. In this example, bipolar transistors having the second high-resistance layer with a doping concentration of 1×10¹⁷ cm⁻³ (indicated by a triangle in FIG. 8), and 3×10¹⁷ cm⁻³ (indicated by a circle in FIG. 8) were produced as test samples. The graph of FIG. 8 shows a total of six samples.

In the samples having the second high-resistance layer with a doping concentration of 3×10¹⁷ cm⁻³, i.e., the sample produced for comparison had a current amplification factor of 9 when the thickness of the recombination suppressing region 17 was set to be 100 nm (comparative example 1) which was a half of the thickness (200 nm) of the second high-resistance region 15. Also, the sample (comparative example 2) having the recombination suppressing region 17 made thin to be 50 nm had a current amplification factor of 20. This is because recombination of an electron with a hole is not sufficiently suppressed in the SiC surface of the recombination suppressing region 17.

Also, according to the comparative examples, when the recombination suppressing region 17 was made further thin to be substantially 0 nm, it was possible to produce a bipolar transistor with a high current amplification factor, but it was difficult to control the thickness of the recombination suppressing region 17 to be a desired value, and the current amplification factor became varied as a result. That is, as the recombination suppressing region 17 becomes thinner and thinner, the current amplification factor changes like a curve indicated by a reference numeral 301 in FIG. 8 or changes like a curve indicated by a reference numeral 302. More specifically, in the two samples having the recombination suppressing region 17 thinned to be substantially 0 nm, one (comparative example 4) had a current amplification factor of 60, another (comparative example 3) had a current amplification factor of 20. “Forming thinly so as to be substantially 0 nm” means thinning to be 0 nm as much as possible, but the recombination suppressing region 17 slightly remains like a layer or an island.

On the other hand, like the bipolar transistor 10 of this embodiment, when the doping concentration of the second high-resistance layer was 1×10¹⁷ cm⁻³, if the thickness of the recombination suppressing region 17 was made to be 100 nm (example 1) which was a half of the thickness (200 nm) of the second high-resistance region 15, the current amplification factor was 54. Also, the sample (example 2) having the recombination suppressing region 17 made thin to be 50 nm had the current amplification factor of 60. According to examples 1 and 2, a stable current amplification factor was obtained by thinning the recombination suppressing region 17 to be equal to or smaller than 100 nm.

The explanation returns to the graph of FIG. 7 and table 1.

According to the bipolar transistor (example 201) indicated by a reference numeral 201 in FIG. 7, the doping concentration of the second high-resistance layer was 1×10¹⁷ cm⁻³, the thickness of the second high-resistance region 15 was 0.1 μm, and the thickness of the recombination suppressing region 17 was controlled so as to be equal to or smaller than 0.1 μm.

Also, according to the bipolar transistor (example 202) indicated by a reference numeral 202 in FIG. 7, the doping concentration of the second high-resistance layer was 3×10¹⁶ cm⁻³, the thickness of the second high-resistance region 15 was 0.2 μm, and the thickness of the recombination suppressing region 17 was controlled so as to be equal to or smaller than 0.2 μm.

Also, according to the bipolar transistor indicated by a reference numeral 203 in FIG. 7, the doping concentration of the second high-resistance layer was 5×10¹⁵ cm⁻³, the thickness of the second high-resistance region 15 was 0.4 μm, and the thickness of the recombination suppressing region 17 was controlled so as to be equal to or smaller than 0.4 μm.

A stable and sufficient current amplification factor was obtained in each of examples 201, 202, and 203 (see table 1).

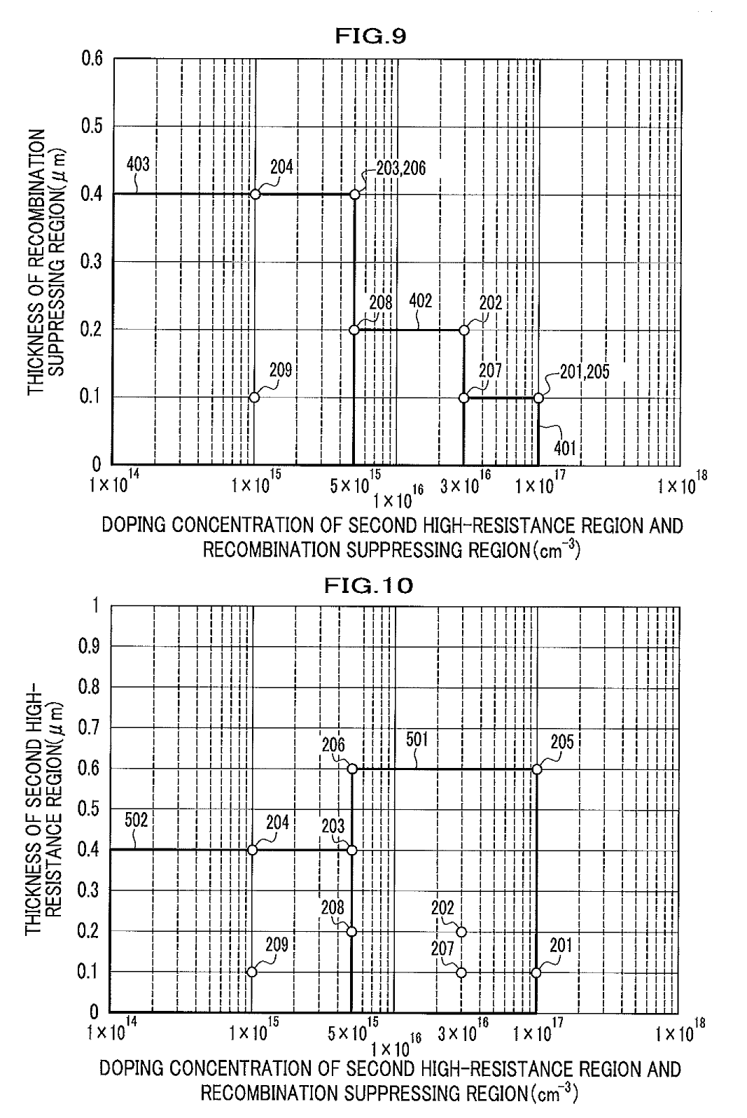

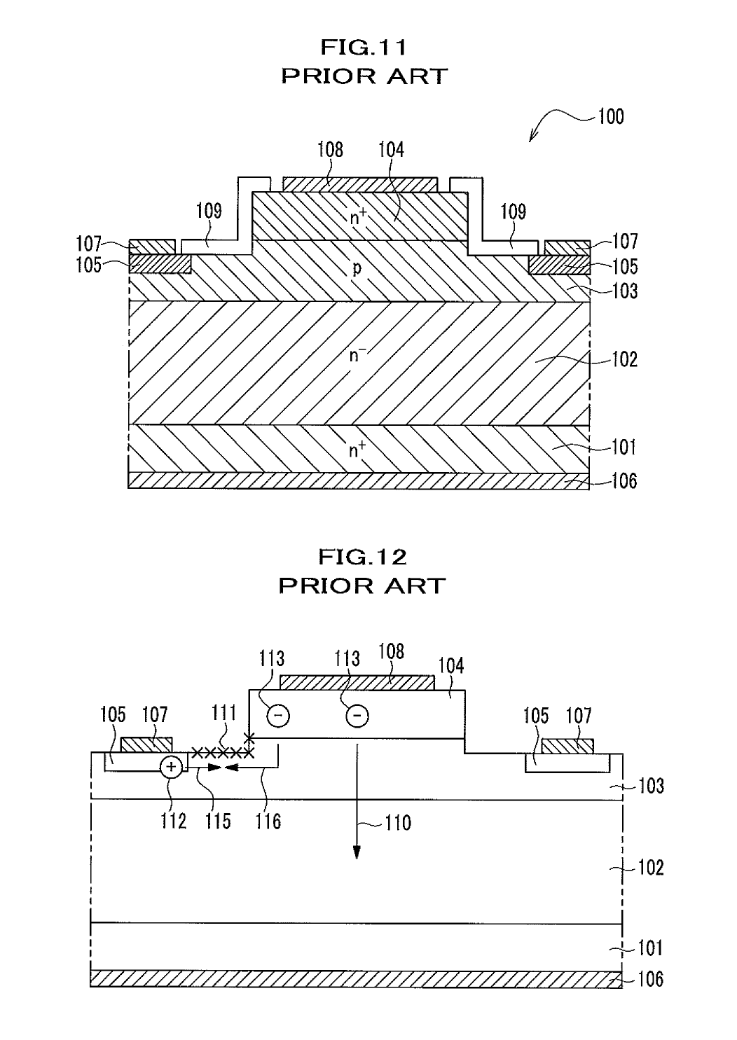

Examples 201, 202, and 203 had different ranges of the doping concentration of the second high-resistance layer, and had different thickness ranges of the recombination suppressing region. Based on such results, a relationship between the doping concentration of the recombination suppressing region 17 (=the doping concentration of the second high-resistance layer) and the thickness of the recombination suppressing region 17 is graphed and shown in FIG. 9. The horizontal axis of the graph of FIG. 9 represents the doping concentrations of the second high-resistance region and the recombination suppressing region (the doping concentration of the second high-resistance layer), and the vertical axis represents the thickness of the recombination suppressing region.

In FIG. 9, small white circles represent results of examples 201 to 209. FIG. 9 also shows a rectangle indicated by a reference numeral 401, a rectangle indicated by a reference numeral 402, and a rectangle indicated by a reference numeral 403. Individual rectangles show an appropriate relationship between the range of the doping concentration of the second high-resistance layer and the range of the thickness of the recombination suppressing region 17 formally separated into three groups.

The width of the rectangle 401 indicates a range where the doping concentration of the second high-resistance layer is equal to or higher than 3×10¹⁶ cm⁻³ and equal to or lower than 1×10¹⁷ cm⁻³, and the height of the rectangle 401 indicates a range where the thickness of the recombination suppressing region 17 is equal to or smaller than 0.1 μm.

The width of the rectangle 402 indicates a range where the doping concentration of the second high-resistance layer exceeds 5×10¹⁵ cm⁻³ and equal to or lower than 3×10¹⁶ cm⁻³, and the height of the rectangle 402 indicates a range where the thickness of the recombination suppressing region 17 is equal to or smaller than 0.2 μm.

The width of the rectangle 403 indicates a range where the doping concentration of the second high-resistance layer is equal to or higher than 1×10¹⁴ cm⁻³ and equal to or lower than 5×10¹⁵ cm⁻³, and the height of the rectangle 403 indicates a range where the thickness of the recombination suppressing region 17 is equal to or smaller than 0.4 μm.

The rectangles 401, 402, and 403 suggest that if the doping concentration of the second high-resistance layer is set to be low, it is fine even if the recombination suppressing region 17 is thickened to some level.

<Relationship Between Doping Concentration of Second High-Resistance Layer and Thickness of Second High-Resistance Region>

Next, in a left range from the center of the graph of FIG. 7, i.e., in an area where the doping concentration of the second high-resistance layer is relatively low, it is important to control the thickness of the second high-resistance region 15 to be thin in order to obtain a high current amplification factor. The reason is apparent from the graph of FIG. 7. As shown in FIG. 7, the thicker the thickness of the second high-resistance region 15 is across the whole area of the doping concentration of the second high-resistance layer, the lower the current amplification factor becomes.

In particular, like the leftmost area in the graph of FIG. 7, in an area where the doping concentration of the second high-resistance layer is extremely low, if the thickness of the second high-resistance region 15 is too thick, a sufficient current amplification factor cannot be obtained. For example, according to the sample having the second high-resistance layer with a doping concentration of 1×10¹⁵ cm⁻³ and the second high-resistance region 15 with a thickness of 0.6 μm, the current amplification factor becomes not to satisfy a value 50.

According to the bipolar transistor (example 204) indicated by a reference numeral 204 in FIG. 7, the doping concentration of the second high-resistance layer was 1×10¹⁵ cm⁻³, the thickness of the second high-resistance region 15 was 0.4 μm, and the thickness of the recombination suppressing region 17 was controlled to be equal to or smaller than .0.4 μm. In this case, a current amplification factor exceeding 60 was obtained. Also, as shown in FIG. 7, when the thickness of the second high-resistance region 15 was 0.4 μm (indicated by a rectangle in FIG. 7), in a range where the doping concentration of the second high-resistance layer was equal to or lower than 1×10¹⁷ cm⁻³, no sample had a current amplification factor changed. Accordingly, it becomes clear that if the doping concentration of the second high-resistance layer is equal to or lower than 1×10¹⁷ cm⁻³ and the thickness of the second high-resistance region 15 is equal to or smaller than 0.4 μm, a sufficient current amplification factor can be obtained.

However, if the thickness of the second high-resistance region 15 is set to be larger than 0.4 μm, a sufficient current amplification factor may be obtained in some cases. For example, according to the bipolar transistor (example 205) indicated by a reference numeral 205 in FIG. 7, the doping concentration of the second high-resistance layer was 1×10¹⁷ cm⁻³, the thickness of the second high-resistance region 15 was 0.6 μm, and the thickness of the recombination suppressing region 17 was controlled to be equal to or smaller than .0.1 μm. In this case, the current amplification factor was 60. Also, according to the bipolar transistor (example 206) indicated by a reference numeral 206 in FIG. 7, the doping concentration of the second high-resistance layer was 5×10¹⁵ cm⁻³, the thickness of the second high-resistance region 15 was 0.6 μm, and the thickness of the recombination suppressing region 17 was controlled to be equal to or smaller than .0.4 μm. In this case, the current amplification factor was also 60.

Examples 204, 205, and 206 had different ranges of the doping concentration of the second high-resistance region 15, and had different thickness ranges of the second high-resistance region 15. Based on such results, a relationship between the doping concentration of the second high-resistance region 15 (=the doping concentration of the second high-resistance layer) and the thickness of the second high-resistance region 15 are graphed and shown in FIG. 10. The horizontal axis of the graph of FIG. 10 represents the doping concentrations of the second high-resistance region and the recombination suppressing region (the doping concentration of the second high-resistance layer), and the vertical axis represents the thickness of the second high-resistance region.

In FIG. 10, small white circles represent results of examples 201 to 209. FIG. 10 also shows a rectangle indicated by a reference numeral 501, and a rectangle indicated by a reference numeral 502. Individual rectangles show an appropriate relationship between the range of the doping concentration of the second high-resistance layer and the range of the thickness of the second high-resistance region 15 formally separated into two groups.

The width of the rectangle 501 indicates a range where the doping concentration of the second high-resistance layer is equal to or higher than 5×10¹⁵ cm⁻³ and equal to or lower than 1×10¹⁷ cm⁻³, and the height of the rectangle 501 indicates a range where the thickness of the second high-resistance region 15 is equal to or smaller than 0.6 μm.

The width of the rectangle 502 indicates a range where the doping concentration of the second high-resistance layer is equal to or higher than 1×10¹⁴ cm⁻³ and equal to or lower than 5×10¹⁵ cm⁻³, and the height of the rectangle 502 indicates a range where the thickness of the second high-resistance region 15 is equal to or smaller than 0.4 μm.

The rectangle 501 in those rectangles can be divided into two pieces in the width direction. One of the divided pieces is in a range where the doping concentration of the second high-resistance layer is equal to or higher than 3×10¹⁶ cm⁻³ and equal to or lower than 1×10¹⁷ cm⁻³. This doping concentration range and the range where the thickness of the recombination suppressing region 17 is equal to or smaller than 0.1 μm (i.e., the rectangle 401 in FIG. 9) include example 205. Also, another of the divided pieces is a range where the doping concentration of the second high-resistance layer exceeds 5×10¹⁵ cm⁻³ and equal to or lower than 3×10¹⁶ cm⁻³. Within this doping concentration range and the range where the thickness of the recombination suppressing region 17 is equal to or smaller than 0.2 μm (i.e., the rectangle 402 in FIG. 9), it is fine if the thickness of the second high-resistance region 15 is 0.6 μm.

As explained above, according to the bipolar transistor 10 of this embodiment, the doping concentration of the second high-resistance layer (the second high-resistance region 15 and the recombination suppressing region 17) is controlled so as to have a doping concentration of equal to or lower than 1×10¹⁷ cm⁻³, a thickness of the recombination suppressing region 17 sufficient in production can be secured. As a result, it is possible to produce a bipolar transistor with a high current amplification factor through an easy production process with a high yield.

The explanation was given of the preferable embodiment of the bipolar semiconductor device of the present invention, but the present invention is not limited to the foregoing embodiment. For example, in the foregoing embodiment, the explanation was given of a bipolar transistor, but the bipolar semiconductor device of the present invention can be other bipolar semiconductor devices. The specific values of the thickness of each layer and ion injection energy amount are just examples, and can be changed within the scope and the spirit of the present invention.

The invention claimed is:

1. A bipolar semiconductor device comprising:
a semiconductor crystal substrate comprising:
a collector region comprising a low-resistance layer of a first conductive type formed in one surface of the semiconductor crystal substrate;
a first high-resistance region of the first conductive type on the collector region;
a low-resistance base region of a second conductive type on the first high-resistance region;
a low-resistance emitter region of the first conductive type formed in another surface of the semiconductor crystal substrate;
a second high-resistance region of the first conductive type between the emitter region and the base region, contacting the emitter region;
a high-resistance recombination suppressing region of the first conductive type between the emitter region and the base region around the second high-resistance region, adjoining the second high-resistance region; and
a low-resistance base contact region of the second conductive type, adjoining the recombination suppressing region, contacting the base region,
wherein each of doping concentrations of the second high-resistance region and the recombination suppressing region is equal to or lower than 1×10¹⁷ cm⁻³.

2. The bipolar semiconductor device according to claim 1, wherein each of doping concentrations of the first conductive type second high-resistance region and the recombination suppressing region is equal to or higher than 3×10¹⁶ cm⁻³ and a thickness of the recombination suppressing region is equal to or smaller than 0.1 μm.

3. The bipolar semiconductor device according to claim 1, wherein each of doping concentrations of the first conductive type second high-resistance region and the recombination suppressing region exceeds 5×10¹⁵ cm⁻³ and is equal to or lower than 3×10¹⁶ cm⁻³, and a thickness of the recombination suppressing region is equal to or smaller than 0.2 μm.

4. The bipolar semiconductor device according to claim 1, wherein each of doping concentrations of the first conductive type second high-resistance region and the recombination suppressing region is equal to or lower than 5×10¹⁵ cm⁻³ and a thickness of the recombination suppressing region is equal to or smaller than 0.4 μm.

5. The bipolar semiconductor device according to claim 2, wherein a thickness of the first conductive type second high-resistance region is equal to or smaller than 0.6 μm.

6. The bipolar semiconductor device according to claim 3, wherein a thickness of the first conductive type second high-resistance region is equal to or smaller than 0.6 μm.

7. The bipolar semiconductor device according to claim 4, wherein a thickness of the first conductive type second high-resistance region is equal to or smaller than 0.4 μm.

8. A method of producing a bipolar semiconductor device comprising the steps of:
forming a first high-resistance layer of a first conductive type on a low-resistance semiconductor substrate of the first conductive type;
forming a low-resistance base region of a second conductive type;
forming a second high-resistance layer of the first conductive type that has a doping concentration equal to or lower than 1×10¹⁷ cm⁻³;
forming a low-resistance layer of the first conductive type;
partially etching the low-resistance layer and the second high-resistance layer to form an emitter region, and etching a surface of the second high-resistance layer to be exposed as a recombination suppressing region around the emitter region;
forming a low-resistance base contact region which adjoins the recombination suppressing region and which is joined to the base region;
forming a base electrode, an emitter electrode, and a collector electrode; and
forming an upper-layer electrode on a side of the base electrode side and the emitter electrode side.
